(19) United States
(12) Patent Application Publication
(10) Pub. No.: US 2017/0285092 A1
(43) Pub. Date: Oct. 5, 2017

(54) DIRECTIONAL UNMANNED AERIAL VEHICLE (UAV) LOCALIZATION OF POWER LINE ULTRAVIOLET CORONA USING POINT DETECTORS

(71) Applicant: U.S.A. as represented by the Administrator of the National Aeronautics and Space Administration, WASHINGON, DC (US)

(72) Inventor: ANDREW J. MOORE, WILLIAMSBURG, VA (US)

(73) Assignee: U.S.A. as represented by the Administrator of the National Aeronautics and Space Administration

(21) Appl. No.: 15/086,350

(22) Filed: Mar. 31, 2016

(51) Int. Cl. G01R 31/12; G05D 1/00; G01R 31/02; B64C 39/02

(52) U.S. Cl. CPC G01R 31/1218; B64C 39/024; G05D 1/0088; G01R 31/021; B64C 2201/127; B64C 2201/146; B64C 2201/141; G01J 1/429

(57) ABSTRACT

Systems, methods, and devices of the various embodiments enable the detection and localization of power line corona discharges and/or electrical arcs by an unmanned aerial vehicle (UAV) including an array of ultraviolet (UV) point detectors.

### STATEMENT REGARDING FEDERALLY SPONSORED RESEARCH OR DEVELOPMENT

The invention described herein was made by an employee of the United States Government and may be manufactured and used by or for the Government for governmental purposes without the payment of any royalties thereon or therefore.

### BACKGROUND OF THE INVENTION

High voltage power transmission efficiency is impaired by electrical faults, such as shorts to the ground. In many circumstances, the faults can be identified by imaging in the ultraviolet (UV) band. While faults can be identified by imaging in the UV band, inspecting high voltage power transmission lines is an expensive, time consuming, labor intensive, and dangerous process that requires lineman to travel the length of the lines, often by helicopter, to collect and analyze images.

### BRIEF SUMMARY OF TIE INVENTION

The systems, methods, and devices of the various embodiments enable the detection and localization of power line corona discharges and/or electrical arcs by an unmanned aerial vehicle (UAV) including an array of ultraviolet (UV) point detectors.

These and other features, advantages, and objects of the present invention will be further understood and appreciated by those skilled in the art by reference to the following specification, claims, and appended drawings.

### BRIEF DESCRIPTION OF THE SEVERAL VIEWS OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1 is a block diagram of an embodiment unmanned aerial vehicle (UAV).

FIG. 2 illustrates an embodiment method for directional localization of power line coronas and/or arcs using UV point detection.

FIG. 3 includes an example UV image and graph of the Difference of Box (DoB) versus kernel size for that image created according to an embodiment.

FIG. 4 includes images showing the results of embodiment operations to analyze visible and UV video channels together

### DETAILED DESCRIPTION OF THE INVENTION

For purposes of description herein, it is to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

The word “exemplary” is used herein to mean “serving as an example, instance, or illustration.” Any implementation described herein as “exemplary” is not necessarily to be construed as preferred or advantageous over other implementations.

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

Identifying and localizing faults in power systems may be important for many reasons including avoiding dangers in power systems, such as power outages, power system equipment damage, human injury, etc. Faults in power systems are often indicated by corona discharges (also referred to as coronas) and/or electrical arcs (also referred to as arcs). Coronas may be asymmetrical (e.g., having a “brush” morphology), and often discharge into the air while generating relatively low heat. Most coronas may be benign, but some may be dangerous and require immediate attention. Benign and dangerous coronas may look similar, but the specific power system structure producing the coronas may indicate whether the corona is benign or dangerous. Arcs may be circular and symmetric, and tend to pulse (or pop) discharge between two surfaces with relatively high heat generation. In contrast to coronas, generally all arcs are dangerous due to the arcs' high heat generation.

The systems, methods, and devices of the various embodiments enable the detection and localization of power line coronas and/or arcs by an unmanned aerial vehicle (UAV) including an array of ultraviolet (UV) point detectors.

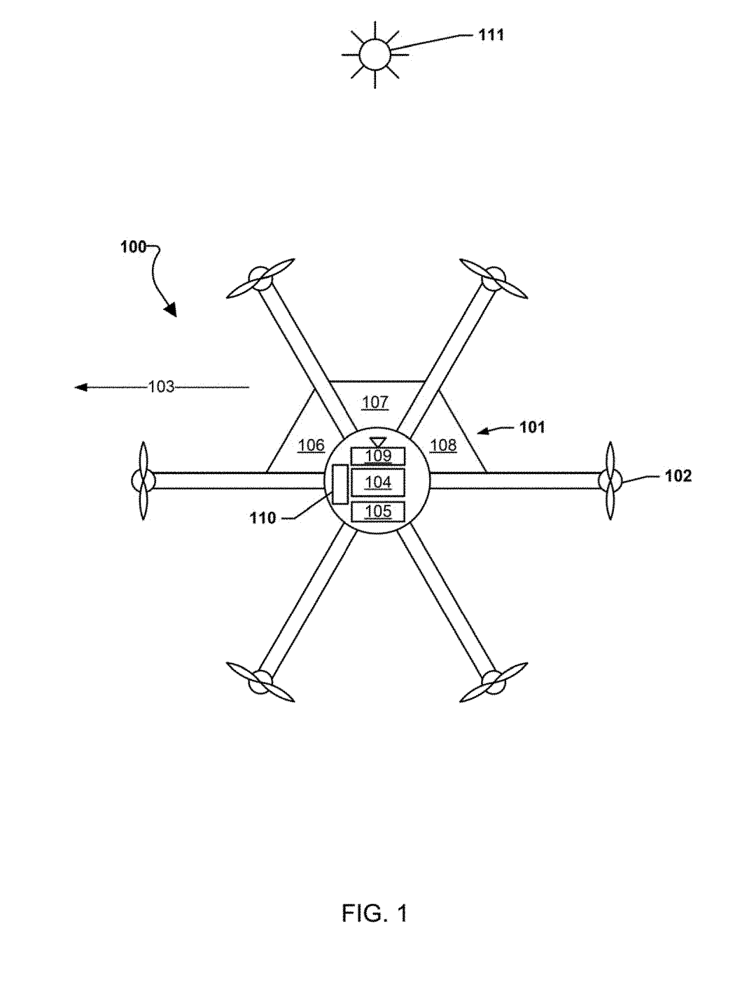

FIG. 1 is a block diagram of an embodiment UAV 100. The UAV 100 may include a UAV body 101 supporting various components, such as engines 102, one or more processor 104, one or more power source 105, one or more UV point detectors, such as three UV point detectors 106, 107, and 108, one or more cameras 109, and one or more wireless transceivers 110. Additionally, the UAV may include other components, such as landing gear (e.g., wheels, skids, legs, etc.), flight controls (e.g., ailerons, flaps, rudders, etc.), positioning systems (e.g., gyros, accelerometers, altimeters, Global Positioning System (GPS) sensors, etc.) or any other structures that may be suitable for use on a UAV. The UAV 100 may be part of a UAV system that may include the UAV 100, optional additional UAVs, and one or more ground station computers in communication with the UAV 100 and optional additional UAVs.

The engines 102 may be any type engines, such as electric engines, combustion engines, etc. The engines 102 may drive propellers or other thrust generating structures. The engines 102 may be connected the processor 104, and the operation of the engines 102 may be controlled by the processor 104.

The power source 105 may be any type power source, such as a battery, combustion engine coupled to a generator, etc. The power source 105 may be connected to the engines 102, and the power source 105 may provide power to the engines 102. The power source 105 may be connected to the processor 104. The processor 104 may control the operation of the power source 105 and/or the power source 105 may power the processor 104.

The UV point detectors 106, 107, and 108 may be connected to the processor 104 and/or the power source 105. In an embodiment, each UV point detector 106, 107, and 108 may be a single channel detector. For example, the UV point detectors 106, 107, and 108 may be UV sensors as described in Kim et al. “The Characteristics of UV Strength According to Corona Discharge from Polymer Insulators Using a UV Sensor and Optic Lens” IEEE Transactions on Power Delivery, Vol. 26, No. 3, Jul. 3, 2011 (hereinafter “Kim et al.”), the entire contents of which are incorporated by reference herein. The UV point detectors 106, 107, and 108 may be solar blind and may be configured to detect UV emissions from coronas and/or arcs in a manner similar to the UV sensors described by Kim et al. as referenced above and/or the UV sensors and signal collection optics as described in Engelhaupt, et al. “Autonomous Long-Range Open Area Fire Detection and Reporting,” published in Thermosense XXVII, edited by Peacock, et al., Proceedings of SPIE Vol. 5782, Mar. 28, 2005 (hereinafter “Engelhaupt, et al.”), the entire contents of which are incorporated by reference herein. The processor 104 may control the operation of the UV point detectors 106, 107, and 108.

The camera 109 may be connected to the processor 104 and power source 105, and the camera 109 may be a camera configured to collect images in one or more bands, such as the UV band, infrared (IR) band, and/or visible light band. In some embodiments, a single camera 109 may collect different bands, e.g., various combinations of UV, IR, and/or visible light, and output different channels for each band. In some embodiments, separate cameras 109 for each band selected for collection, e.g., one or more of UV, IR, and/or visible light, may be included on the UAV 100, and the different inputs from each camera 109 may be treated as different channels by the processor 104. The camera 109 may be a video camera capturing multiple frames sequentially. The processor 104 may control the operations of the camera 109.

The transceiver 110 may be connected to the processor 104 and power source 105, and the transceiver 110 may be any type wireless transceiver (or receiver and transmitter pair) configured to transmit/receive wireless signals to/from the UAV 100. As examples, the transceiver 110 may transmit/receive data signals from a ground station, satellite, network access point, operator control console, etc., for various reasons, including providing control signals to the processor 104, providing measured data and/or analyzed data from the UV point detectors 106, 107, and 108, camera 109, and/or processor 104 to relevant users of the drone, receiving air traffic management signals, reporting location, receiving software updates, receiving waypoint and other flight pattern information, reporting diagnostic results, etc.

While the UAV 100 is illustrated as a hexacopter type UAV, a hexacopter type UAV is used merely as an example UAV design to better illustrate the various embodiments. Other type UAVs, such as single rotor UAVs, octocopter UAVs, wing-born flight UAVs, or any other type UAV, may be substituted for the hexacopter type UAV used in the various examples.

In operation, the UV point detectors 106, 107, and 108 may be controlled by the processor 104 to detect UV transmissions from coronas and/or arcs as the UAV 100 flies in a forward direction 103 past a corona or arc 111. The processor 104 may monitor the outputs of the UV point detectors 106, 107, and 108, and when a UV reading indicative of a corona or arc 111 is detected the processor 104 may adjust the orientation of the UAV 100 such that the camera 109 is pointed at the corona or arc 111. The camera 109 may record one or more frames of imagery of the corona or arc 111, and the processor 104 may analyze the one or more frames of imagery of the corona or arc 111. Analyzing the one or more frames of imagery of the corona or arc 111 may include: applying video stabilization techniques to track the detected UV emissions from the corona or arc 111; removing background and/or camera motion by horizontally and/or vertically stabilizing frames of the detected UV emissions from the corona or arc 111 and superimposing them on one another; identifying the center and boundary of the corona or arc 111; overlaying video images from different channels of the camera 109 on one another; adding indications (e.g., boxes, colors, and/or other indicators) to the images); and/or applying machine vision techniques to the one or more frames of the imagery of the corona or arc 111 to determine the type of equipment from which the corona or arc 111 may be originating. The results of the analysis of the one or more frames of imagery of the corona or arc 111, the one or more frames of imagery of the corona or arc 111, indications/measurements of the corona or arc 111 from the UV point detectors 106, 107, and 108, and/or other data (e.g., GPS coordinates) may be sent from the processor 104 via the transceiver 110 to another device, e.g., a user's computer, server of a power company monitoring station, etc., to enable a user to use the results of the analysis, imagery of the corona or arc 111, indications/measurements of the corona or arc 111, and/or other data to take appropriate responses to the corona or arc 111.

In an alternative embodiment, the analysis operations discussed above as performed by processor 104 may be performed by a processor remote from the UAV 100, such as a processor of a ground station computer. In such an embodiment, the processor 104 may control the transceiver 110 to send data from the UV point detectors 106, 107, and 108 and/or camera 109 to the processor remote from the UAV 100, and processor remote from the UAV 100 may analyze and data from the UV point detectors 106, 107, and 108 and/or camera 109 to detect coronas or arcs as discussed herein.

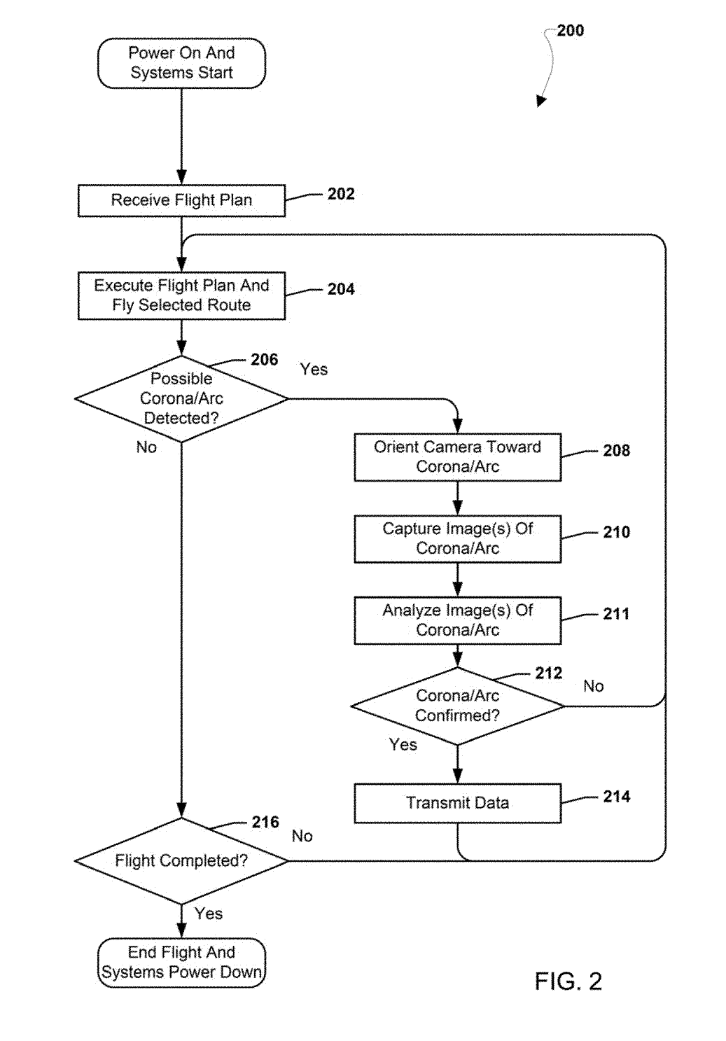

FIG. 2 illustrates an embodiment method 200 for directional localization of power line coronas and/or arcs using UV point detection. In an embodiment, the operations of method 200 may be performed by a processor of a UAV, such as processor 104 of UAV 100 described above and/or a processor remote from the UAV, such as a processor of a ground station computer. The operations of method 200 may begin upon power on and system start of the UAV. At power on and system start the engines, positioning system, and other control systems of the UAV, as well as the UV point detectors and cameras, such as UV point 106, 107, and 108 and camera 109, may be powered on and begin operating (e.g., capturing UV measurements and video, logging position, providing thrust, etc.).

In block 202 a flight plan may be received by the processor of the UAV. For example, the flight plan may be a series of way points arranged along a set of power lines selected for monitoring. The series of way points may constitute a selected route for the UAV. As a specific example, the flight plan may be a flight plan compatible with NASA's Unmanned Aerial System Traffic Management (UTM) system.

In block 204 the processor may execute the flight plan and fly the UAV along the selected route. For example, the processor may control the UAV's engines, control surfaces, positioning system, power source, and any other on-board system as needed to fly the UAV from waypoint to waypoint along the selected route corresponding to the power lines to be inspected.

In determination block 206 the processor may determine whether a possible corona or arc is detected. For example, the processor may periodically or continually monitor the outputs of the UV point detectors, such as UV point detectors 106, 107, and 108, to determine whether a UV source above a threshold is observed by one or more of the UV detectors. In response to determining no possible corona or arc is detected (i.e., determination block 206=“No”), the processor may determine whether the flight is completed in determination block 216. In response to determining the flight is not completed (i.e., determination block 216=“No”), the processor may continue to execute the flight plan and fly the selected route as described above with reference to block 204 and continue to monitor for possible coronas and arcs as described with reference to determination block 206.

In response to detecting a possible corona or arc (i.e., determination block 206=“Yes”), in block 208 the processor may orient the camera toward the corona or arc. For example, the processor may compare the relative UV measurements of the UV point detectors 106, 107, 108 to identify a most likely direction for the corona relative the forward direction of travel of the UAV and may turn the UAV accordingly to focus the camera toward the corona or arc. In block 210 the processor may control the camera to capture one or more image of the corona or arc. In block 211 the processor may analyze the images of the corona or arc. Analyzing the images of the corona or arc may include applying image processing techniques to the images to confirm whether or not a corona or arc is present in the images, to determine how many coronas or arcs may be present in the images, to identify the boundaries of any coronas or arcs in the images, to identify the center of the coronas or arcs in the images, and/or to apply indications to the images.

In determination block 212 the processor may determine or confirm whether any coronas or arcs were identified in the images. In response to determining no coronas or arcs were identified (i.e., determination block 212=“No”), the processor may return to executing the flight plan and fly the selected route as described above with reference to block 204 and continue to monitor for possible coronas and arcs as described with reference to determination block 206. In response to determining a corona and/or arc is present (i.e., determination block 212=“Yes”), in block 214 the processor may transmit data to one or more connected devices, such as via a network connection established via transceiver 110. For example, the data transmitted may be one or more images of the corona or arc, such as images including indications of regions of interest, data indicating the location of the UAV when the images were collected, raw data from the UV point detectors or camera, data indicating the camera direction, etc. In response to transmitting the data, the processor may return to executing the flight plan and fly the selected route as described above with reference to block 204 and continue to monitor for possible coronas and arcs as described with reference to determination block 206.

In response to determining the flight is completed (i.e., determination block 216=“Yes”), the processor may end the flight and power down appropriate systems.

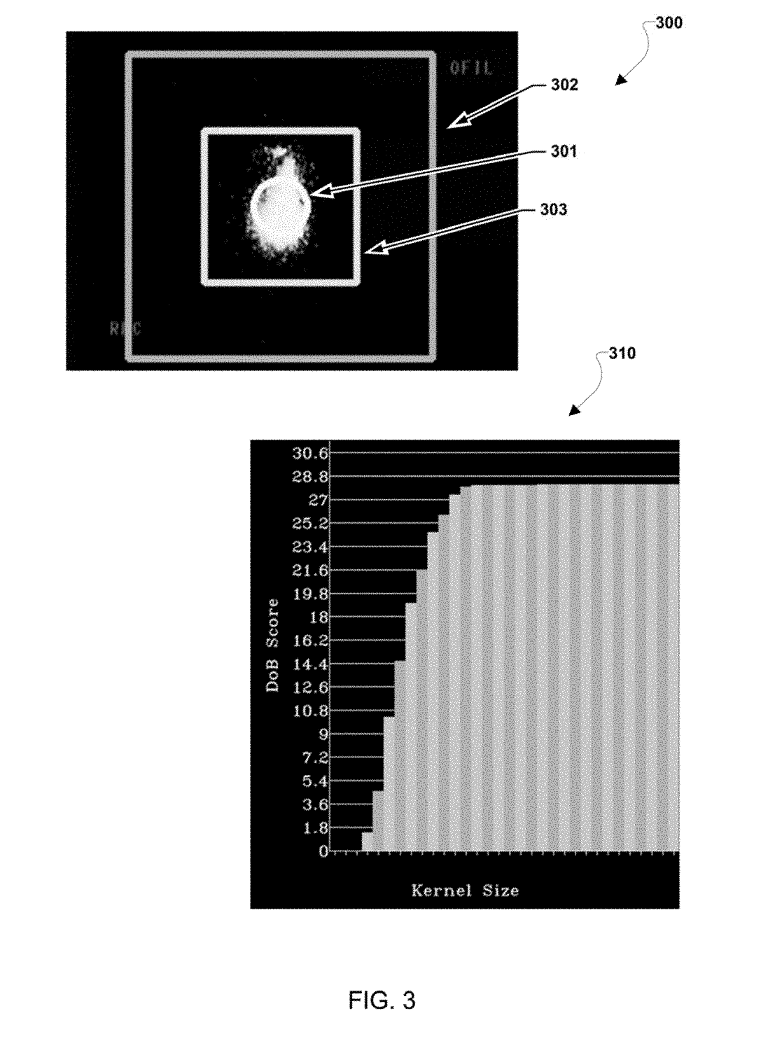

FIG. 3 includes an example UV image 300 and graph 310 of the Difference of Box (DoB) versus kernel size for that image created according to an embodiment. The image 300 may be generated by analyzing the images of a UV camera capturing a corona. The center of the corona may be indicated by the ring 301 around the corona. The inner box 303 may identify a region of interest on which to zoom in on for an operator/user viewing the image. The area of the inner box 303 may fluctuate based on the size of the corona. The outer box 302 may identify a context area outside the corona that may be helpful to an operator/user viewing the image.

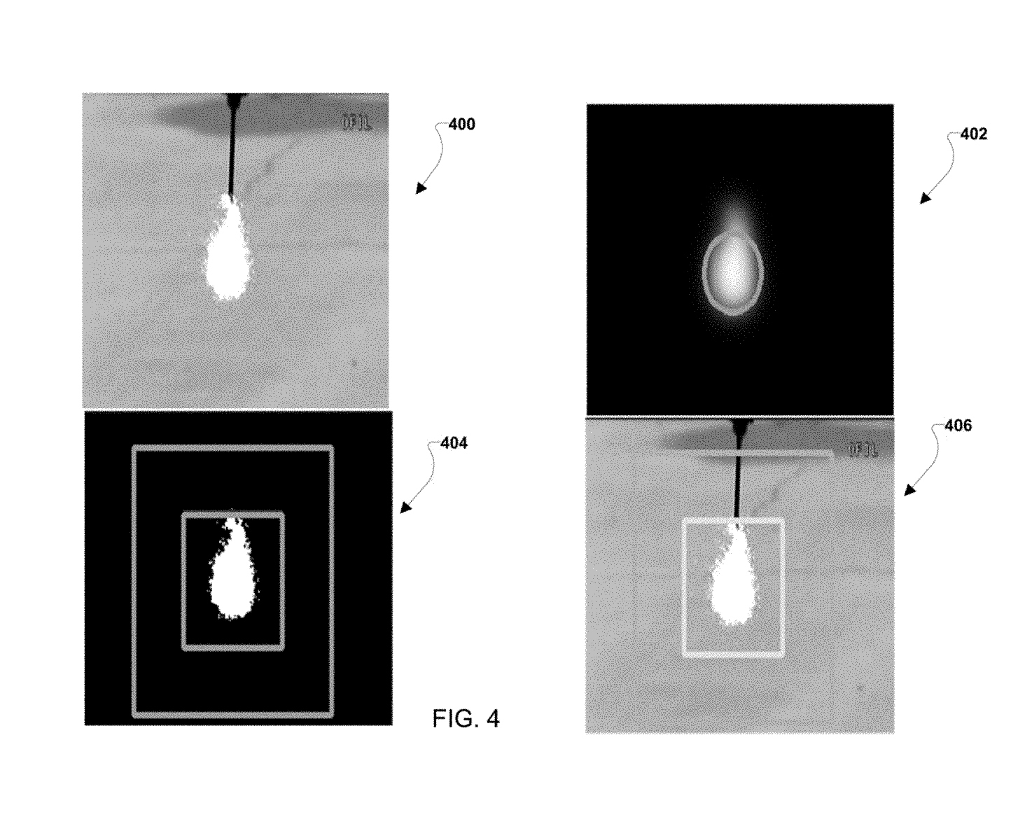

FIG. 4 includes images showing the results of embodiment operations to analyze visible and UV video channels together. In a first operation, the UV video frames from the UV channels received from the camera may be rendered resulting in a UV image 400. Next the center of the corona on the UV video channel frames may be found and a ring centered over the center of the corona may be indicated in the UV image 402. The boundary of the corona on the UV video channel frames may be found and boxes sized based on the boundary of the corona, such as a close-up inspection box (e.g., a colored green box) and a context picture box (e.g., a colored red box), may be indicated in the UV image 404. The UV center and the boxes sized based on the boundary of the corona may then be overlaid with the UV image to produce a combined image 406. In an embodiment, the UV center and the boxes sized based on the boundary of the corona may be overlaid with the UV image and a visible image rendered from the visible channels received from the camera to produce a combined image.

While discussed herein in relation to identifying coronas and arcs in power lines, the various embodiments may also be applicable to fault detection in port facilities, rail lines, pipelines, trolleys, levees, bridges, and dams.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

In the various embodiments described herein the functions described may be implemented in hardware, software, firmware, or any combination thereof. If implemented in software, the functions may be stored as one or more instructions or code on a non-transitory computer-readable medium or non-transitory processor-readable medium. The steps of a method or algorithm disclosed herein may be embodied in a processor-executable software module which may reside on a non-transitory computer-readable or processor-readable storage medium. Non-transitory computer-readable or processor-readable storage media may be any storage media that may be accessed by a processor. By way of example but not limitation, such non-transitory computer-readable or processor-readable media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a processor. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable medium and/or computer-readable medium, which may be incorporated into a computer program product.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. An unmanned aerial vehicle (UAV) system, comprising:
a UAV body;
at least one ultraviolet (UV) point detector coupled to the UAV body; and
a processor in communication with the at least one IN point detector, wherein the processor is configured with processor-executable instructions to perform operations comprising:
detecting a corona or arc generated by a power system based on UV measurements received from the at least one UV point detector.

2. The UAV system of claim 1, wherein the at least one UV point detector is three UV point detectors.

3. The UAV system of claim 2, wherein the processor is configured with processor-executable instructions to perform operations further comprising:
determining a direction of the corona or arc based on the UV measurements received from the three UV point detectors.

4. The UAV system of claim 3, further comprising a UV and visible light camera coupled to the UAV body and connected to the processor,
wherein the processor is configured with processor-executable instructions to perform operations further comprising:
orienting the UAV such that the camera is pointed in the direction of the corona or arc; and
capturing an image of the corona or arc via the camera.

5. The UAV system of claim 4, wherein the processor is configured with processor-executable instructions to perform operations further comprising:
analyzing the image of the corona or arc to identify a center of the corona or arc and a boundary of the corona or arc.

6. The UAV system of claim 5, wherein the image of the corona or arc is a UV image of the corona or arc.

7. The UAV system of claim 6, wherein analyzing the image of the corona or arc to identify a center of the corona or arc and a boundary of the corona or arc comprises:
determining the center of the corona or arc in the UV image;
indicating a ring around the center of the corona or arc in the UV image;
determining the boundary of the corona or arc in the UV image;
indicating at least one box around the corona or arc in the UV image; and
overlaying the ring, the at least one box, and the UV image.

8. The UAV system of claim 7, wherein the processor is a processor of a device remote from the UAV body.

9. The UAV system of claim 7, wherein the processor is coupled to the UAV body and connected to the three UV point detectors.

10. The UAV of claim 9, further comprising a transceiver coupled to the UAV body and connected to the processor,
wherein the processor is configured with processor-executable instructions to perform operations further comprising transmitting data associated with the corona or arc to another device.

11. The UAV of claim 10, wherein the processor is configured with processor-executable instructions to perform operations further comprising controlling the UAV to fly a flight path along power lines.

12. A method for detection and localization of corona discharges or electrical arcs by an unmanned aerial vehicle (UAV), comprising:
controlling a flight control of the UAV by a processor of the UAV to fly the UAV along a selected route; and
detecting, by the processor of the UAV, a corona or arc along the selected route based on ultraviolet (UV) measurements received from at least one UV point detector on the UAV,
wherein the corona or arc is generated by a power system.

13. The method of claim 12, wherein the at least one UV point detector is three UV point detectors.

14. The method of claim 13, further comprising determining, by the processor of the UAV, a direction of the corona or arc based on the UV measurements received from the three UV point detectors.

15. The method of claim 14, further comprising:
controlling the flight control of the UAV by the processor of the UAV to orient the UAV such that a UV and visible light camera of the UAV is pointed in the direction of the corona or arc; and
capturing an image of the corona or arc via the camera.

16. The method of claim 15, further comprising analyzing, by the processor of the UAV, the image of the corona or arc to identify a center of the corona or arc and a boundary of the corona or arc.

17. The method of claim 16, wherein analyzing, by the processor of the UAV, the image of the corona or arc to identify a center of the corona or arc and a boundary of the corona or arc comprises:
determining the center of the corona or arc in a UV image of the corona or arc;
indicating a ring around the center of the corona or arc in the UV image;
determining the boundary of the corona or arc in the UV image;
indicating at least one box around the corona or arc in the UV image; and
overlaying the ring, the at least one box, and the UV image.

18. The method of claim 17, further comprising transmitting data associated with the corona or arc to another device via a transmitter of the UAV.

19. The method of claim 18, wherein the selected route is along power lines.
